(19) United States
(12) Patent Application Publication
(10) Pub. No.: US 2025/0204060 A1
(43) Pub. Date: Jun. 19, 2025

(54) SEMICONDUCTOR STACK AND LIGHT-RECEIVING DEVICE

(71) Applicant: SUMITOMO ELECTRIC INDUSTRIES, LTD., Osaka (JP)

(72) Inventors: Takuma FUYUKI, Osaka (JP); Susumu YOSHIMOTO, Osaka (JP)

(73) Assignee: SUMITOMO ELECTRIC INDUSTRIES, LTD., Osaka (JP)

(21) Appl. No.: 18/957,775

(22) Filed: Nov. 24, 2024

(30) Foreign Application Priority Data
Dec. 13, 2023 (JP) 2023-210313

(51) Int. Cl. H01L 31/107; H01L 31/0216; H01L 31/0304; H01L 31/0352

(52) U.S. Cl. CPC H10F 30/2255; H10F 77/1248; H10F 77/148; H10F 77/306

(57) ABSTRACT

A semiconductor stack includes a first-conductivity-type layer, a multiplication layer, a light absorption layer and a second-conductivity-type layer. The first-conductivity-type layer, the multiplication layer, the light absorption layer, and the second-conductivity-type layer are stacked in this order. The multiplication layer is a superlattice layer including a first element layer and a second element layer. The first element layer is an InP layer and the second element layer is a GaAs₁₋ₓSbₓ layer where x is 0.3 to 1, or the first element layer is an AlᵤGa₁₋ᵤAs₁₋ₓSbₓ layer and the second element layer is an In_{y}Ga_{1-y}As layer where u is 0.2 to 1, x is 0.3 to 1, and y is 0.3 to 1, or the first element layer is an AlᵤGa₁₋ᵤAs₁₋ₓSbₓ layer and the second element layer is a GaAs_{1-z}Sb_{z} layer where u is 0.2 to 1, x is 0.3 to 1, and z is 0.3 to 1.

### CROSS REFERENCE TO RELATED APPLICATIONS

This application claims priority based on Japanese Patent Application No. 2023-210313 filed on Dec. 13, 2023, and the entire contents of the Japanese patent application are incorporated herein by reference.

### TECHNICAL FIELD

The present disclosure relates to a semiconductor stack and a light-receiving device.

### BACKGROUND

In semiconductor light-receiving devices (photodiodes), an avalanche photodiode that achieves high sensitivity by employing a multiplication layer is known. A strong electric field is applied to the multiplication layer of the avalanche photodiode, and carriers (electrons or holes) generated in the light absorption layer are accelerated by the electric field and collide with atoms in the multiplication layer. As a result, the atoms in the multiplication layer are ionized, and additional carriers are generated. In this way, the number of carriers in the multiplication layer is increased, and thus high sensitivity is obtained.

Here, when the number of both electrons and holes increases in the multiplication layer, noise increases and sensitivity decreases. In order to improve sensitivity, it is required to increase the number of only one of electrons and holes, that is, to reduce a value obtained by dividing a smaller one of the ionization rate α of electrons and the ionization rate β of holes in the multiplication layer by a larger one (a smaller one of α/β and β/α; ionization rate ratio).

From such a viewpoint, it has been proposed to adopt a superlattice layer in which two layers formed of different semiconductor materials are alternately stacked, instead of a layer formed of a single semiconductor material as the multiplication layer. Specifically, it has been proposed to adopt, as the multiplication layer, a superlattice layer in which an InP layer (indium phosphide layer) and an InGaAs layer (indium gallium arsenide layer) are stacked, or a superlattice layer in which an AlInAs layer (aluminum indium arsenide layer) and an InGaAs layer are stacked (see, for example, Non-patent literature 1 and Non-patent literature 2).
[Non-patent literature 1] F. Osaka, et al., “Electron and Hole Impact Ionization Rates in InP/Ga_{0.47}In_{0.53}As Superlattice”, IEEE JOURNAL OF QUANTUM ELECTRONICS, VOL. QE-22, NO. 10, October 1986, p. 1986 to 1991
[Non-patent literature 2] T. Kagawa, et al., “Impact ionization rates in an InGaAs/InAlAs superlattice”, Appl. Phys. Lett. 55, (1989), p. 993 to 995

### SUMMARY

A semiconductor stack according to the present disclosure includes a first-conductivity-type layer of a first conductivity type, the first-conductivity-type layer being formed of a III-V compound semiconductor, a multiplication layer formed of a III-V compound semiconductor, a light absorption layer formed of a III-V compound semiconductor and a second-conductivity-type layer of a second conductivity type different from the first conductivity type, the second-conductivity-type layer being formed of a III-V compound semiconductor. The first-conductivity-type layer, the multiplication layer, the light absorption layer, and the second-conductivity-type layer are stacked in this order. The multiplication layer is a superlattice layer including a first element layer and a second element layer disposed in contact with the first element layer. The first element layer is an InP layer and the second element layer is a GaAs₁₋ₓSbₓ layer (gallium arsenide antimonide layer) where x is 0.3 to 1, or the first element layer is an AlᵤGa₁₋ᵤAs₁₋ₓSbₓ layer (aluminum gallium arsenide antimonide layer) and the second element layer is an In_{y}Ga_{1-y}As layer where u is 0.2 to 1, x is 0.3 to 1, and y is 0.3 to 1, or the first element layer is an AlᵤGa₁₋ᵤAs₁₋ₓSbₓ layer and the second element layer is a GaAs_{1-z}Sb_{z} layer where u is 0.2 to 1, x is 0.3 to 1, and z is 0.3 to 1.

### BRIEF DESCRIPTION OF THE DRAWINGS

FIG. 1 is a schematic cross-sectional view showing an example of a structure of a semiconductor stack.

FIG. 2 is a schematic cross-sectional view showing an example of a structure of a multiplication layer.

FIG. 3 is a schematic cross-sectional view showing an example of a structure of a light-receiving device (avalanche photodiode).

FIG. 4 is a schematic cross-sectional view showing another example of a structure of a semiconductor stack.

FIG. 5 is a schematic cross-sectional view showing yet another example of a structure of a semiconductor stack.

### DETAILED DESCRIPTION

As described above, in the avalanche photodiode which is a light-receiving device including a multiplication layer, a multiplication layer having a small ionization rate ratio is required. It is an object of the present disclosure to provide a semiconductor stack and a light-receiving device including a multiplication layer having a small ionization rate ratio.

According to the semiconductor stack above, the semiconductor stack including a multiplication layer having a small ionization rate ratio can be provided.

### Description of Embodiments of Present Disclosure

First, embodiments of the present disclosure will be listed and described. (1) A semiconductor stack according to the present disclosure includes a first-conductivity-type layer of a first conductivity type, the first-conductivity-type layer being formed of a III-V compound semiconductor, a multiplication layer formed of a III-V compound semiconductor, a light absorption layer formed of a III-V compound semiconductor and a second-conductivity-type layer of a second conductivity type different from the first conductivity type, the second-conductivity-type layer being formed of a III-V compound semiconductor. The first-conductivity-type layer, the multiplication layer, the light absorption layer, and the second-conductivity-type layer are stacked in this order. The multiplication layer is a superlattice layer including a first element layer and a second element layer disposed in contact with the first element layer. The first element layer is an InP layer and the second element layer is a GaAs₁₋ₓSbₓ layer where x is 0.3 to 1, or the first element layer is an AlᵤGa₁₋ᵤAs₁₋ₓSbₓ layer and the second element layer is an In_{y}Ga_{1-y}As layer where u is 0.2 to 1, x is 0.3 to 1, and y is 0.3 to 1, or the first element layer is an AlᵤGa₁₋ᵤAs₁₋ₓSbₓ layer and the second element layer is a GaAs_{1-z}Sb_{z} layer where u is 0.2 to 1, x is 0.3 to 1, and z is 0.3 to 1.

In the semiconductor stack of the present disclosure, a superlattice layer including an InP layer and a GaAs₁₋ₓSbₓ layer, a superlattice layer including an AlᵤGa₁₋ᵤ As₁₋ₓSbₓ layer and an In_{y}Ga_{1-y}As layer, or a superlattice layer including an AlᵤGa₁₋ᵤAs₁₋ₓSbₓ layer and a GaAs_{1-z}Sb_{z} layer is employed as the multiplication layer. In these superlattice layers, the difference between the energy level difference ΔEc between the conduction bands of the two layers constituting the superlattice layer and the energy level difference ΔEv between the valence bands is large, and therefore, the ionization rate ratio is small. As a result, according to the semiconductor stack of the present disclosure, the semiconductor stack including a multiplication layer having a small ionization rate ratio can be provided. By fabricating an avalanche photodiode using the semiconductor stack of the present disclosure, a light-receiving device having high sensitivity can be obtained.

(2) In the above (1), a main surface of the multiplication layer on a side of the first-conductivity-type layer and a main surface of the multiplication layer on a side of the light absorption layer may be each formed of the first element layer. This configuration facilitates ensuring good crystallinity in the semiconductor stack.

(3) In the above (2), the first element layer may be an InP layer and the second element layer may be a GaAs₁₋ₓSbₓ layer where x may be 0.3 to 1. The combination of the InP layer and the GaAs₁₋ₓSbₓ layer is particularly suitable as the first element layer and the second element layer constituting the multiplication layer which is a superlattice layer.

(4) In any one of (1) to (3), the semiconductor stack may further includes a first electric-field control layer of the second conductivity type, the first electric-field control layer being formed of a III-V compound semiconductor and disposed between the multiplication layer and the light absorption layer. By adopting such a first electric-field control layer, it becomes easy to stably apply a strong electric field to the multiplication layer.

(5) In the above (4), the semiconductor stack may further includes a second electric-field control layer of the first conductivity type, the second electric-field control layer being formed of a III-V compound semiconductor and disposed between the multiplication layer and the first-conductivity-type layer. By adopting such a second electric-field control layer in addition to the first electric-field control layer, it becomes easier to stably apply a strong electric field to the multiplication layer.

(6) In the above (4) or (5), the semiconductor stack may further includes a compositionally graded layer which is formed of a III-V compound semiconductor and disposed between the first electric-field control layer and the light absorption layer and whose energy level of a band edge has a value between an energy level of a band edge of the first electric-field control layer and an energy level of a band edge of the light absorption layer. By adopting such a compositionally graded layer, the movement of carriers between the first electric-field control layer and the light absorption layer is facilitated, and the operation speed of the light-receiving device is improved.

(7) In the above (6), the compositionally graded layer may include a first main surface which is a main surface on a side of the first electric-field control layer, and a second main surface which is a main surface on a side of the light absorption layer. A composition of the compositionally graded layer may change stepwise such that the energy level of the band edge of the compositionally graded layer approaches the energy level of the band edge of the light absorption layer from the first main surface toward the second main surface. By adopting such a configuration, the movement of carriers between the first electric-field control layer and the light absorption layer is further facilitated, and the operation speed of the light-receiving device is improved.

(8) In the above (6), the compositionally graded layer may include a first main surface which is a main surface on a side of the first electric-field control layer, and a second main surface which is a main surface on a side of the light absorption layer. A composition of the compositionally graded layer may change continuously such that the energy level of the band edge of the compositionally graded layer approaches the energy level of the band edge of the light absorption layer from the first main surface toward the second main surface. By adopting such a configuration, the movement of carriers between the first electric-field control layer and the light absorption layer is further facilitated, and the operation speed of the light-receiving device is improved.

(9) A light-receiving device according to the present disclosure includes the semiconductor stack according to any one of the above (1) to (8), and an electrode disposed on the semiconductor stack. According to the light-receiving device of the present disclosure, a light-receiving device having high sensitivity can be provided by including the semiconductor stack of the present disclosure including the multiplication layer having a small ionization rate ratio.

### DETAILS OF EMBODIMENTS OF PRESENT DISCLOSURE

### First Embodiment

Next, embodiments of a semiconductor stack of the present disclosure will be described with reference to the drawings. In the drawings, the same or corresponding parts are denoted by the same reference characters, and description thereof will not be repeated.

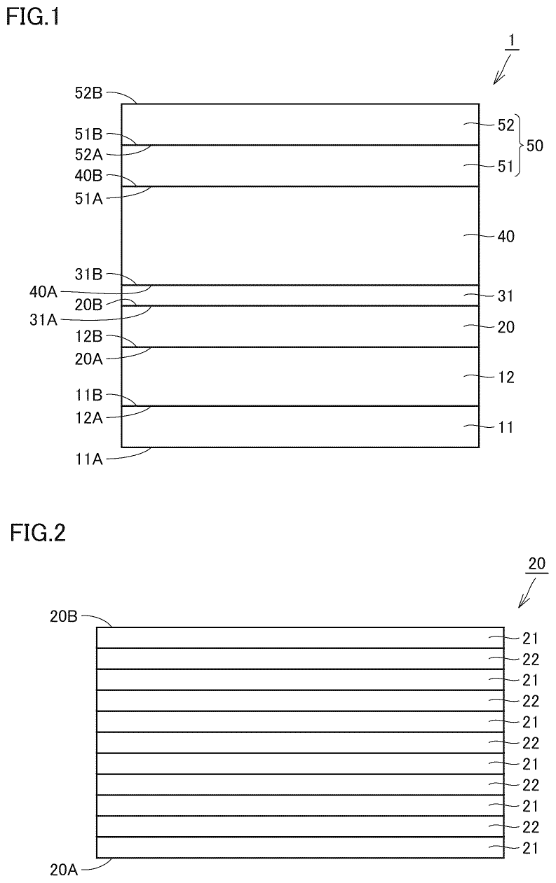

FIG. 1 is a schematic cross-sectional view showing the structure of a semiconductor stack. FIG. 2 is a schematic cross-sectional view showing the structure of a multiplication layer. Referring to FIG. 1, a semiconductor stack 1 according to the present embodiment includes a substrate 11, a buffer layer 12, a multiplication layer 20, a first electric-field control layer 31, a light absorption layer 40, a cap layer 51, and a contact layer 52.

Substrate 11 has a first main surface 11A and a second main surface 11B located on the opposite to first main surface 11A in the thickness direction. Substrate 11 is formed of a group III-V compound. The III-V compound constituting substrate 11 is, for example, InP. InP constituting substrate 11 may contain, for example, Fe (iron) as an impurity. In the present embodiment, substrate 11 is an insulator. The thickness of substrate 11 may be, for example, about 150 μm.

Buffer layer 12 is a semiconductor layer disposed on and in contact with second main surface 11B of substrate 11. Buffer layer 12 has a first main surface 12A and a second main surface 12B located on the opposite to first main surface 12A in the thickness direction. Buffer layer 12 is in contact with second main surface 11B of substrate 11 at first main surface 12A. Buffer layer 12 is formed of a III-V compound semiconductor. As the III-V compound semiconductor constituting buffer layer 12, for example, InP can be adopted. Specifically, for example, InP (p-InP) having a p-type conductivity is adopted as the compound semiconductor constituting buffer layer 12. Buffer layer 12 is a first-conductivity-type layer whose conductivity type is a first conductivity type. The concentration of p-type impurities (impurities that generate holes as majority carriers) contained in the compound semiconductor constituting buffer layer 12 can be set to, for example, about 2×10¹⁸ cm⁻³. The thickness of Buffer layer 12 can be, for example, about 1000 nm.

Multiplication layer 20 is a semiconductor layer disposed on and in contact with second main surface 12B of buffer layer 12. Multiplication layer 20 has a first main surface 20A and a second main surface 20B located on the opposite to first main surface 20A in the thickness direction. Multiplication layer 20 is in contact with second main surface 12B of buffer layer 12 at first main surface 20A. Referring to FIG. 2, multiplication layer 20 is a superlattice layer which is formed of a III-V compound semiconductor and in which a first element layer (barrier layer) 21 and a second element layer (well layer) 22 having respectively different band edge energy levels are alternately stacked. Multiplication layer 20 includes a unit structure including first element layer 21 and second element layer 22 disposed in contact with first element layer 21.

In the present embodiment, first element layer 21 is formed of InP. Second element layer 22 is formed of GaAs₁₋ₓSbₓ. Here, x is 0.3 to 1. In the present embodiment, both first main surface 20A and second main surface 20B of multiplication layer 20 are formed of first element layer 21. That is, both first main surface 20A and second main surface 20B of multiplication layer 20 are formed of InP layers. The lowermost layer and the uppermost layer of multiplication layer 20 are both formed of InP layers. The thickness of first element layer 21 can be, for example, about 20 nm. The thickness of second element layer 22 can be, for example, about 30 nm. The number of unit structures included in multiplication layer 20 can be, for example, about 10. The thickness of multiplication layer 20 can be appropriately adjusted in accordance with the desired characteristics of the light-receiving device to be manufactured. Specifically, a high multiplication factor can be obtained by increasing the thickness of multiplication layer 20. The operation speed can be improved by reducing the thickness of multiplication layer 20.

Referring to FIG. 1, first electric-field control layer 31 is a semiconductor layer disposed on and in contact with second main surface 20B of multiplication layer 20. First electric-field control layer 31 has a first main surface 31A and a second main surface 31B located on the opposite to first main surface 31A in the thickness direction. First electric-field control layer 31 is in contact with second main surface 20B of multiplication layer 20 at first main surface 31A. First electric-field control layer 31 is formed of a III-V compound semiconductor. As the III-V compound semiconductor constituting first electric-field control layer 31, for example, InP can be adopted. Specifically, for example, InP (n-InP) having an n-type conductivity is adopted as the compound semiconductor constituting first electric-field control layer 31. First electric-field control layer 31 is a semiconductor layer having a second conductivity type. The concentration of n-type impurities (impurities that generate electrons as majority carriers) contained in the compound semiconductor constituting first electric-field control layer 31 can be set to, for example, about 5×10¹⁷ cm-3. The concentration of impurities that generate majority carriers is lower in first electric-field control layer 31 than in buffer layer 12. The thickness of first electric-field control layer 31 can be, for example, about 100 nm.

Light absorption layer 40 is a semiconductor layer disposed on and in contact with second main surface 31B of first electric-field control layer 31. Light absorption layer 40 has a first main surface 40A and a second main surface 40B located on the opposite to first main surface 40A in the thickness direction. Light absorption layer 40 is in contact with second main surface 31B of first electric-field control layer 31 at first main surface 40A. Light absorption layer 40 is formed of a III-V compound semiconductor. As the III-V compound semiconductor constituting light absorption layer 40, for example, InGaAs can be adopted. Specifically, for example, undoped InGaAs (ud-InGaAs) is adopted as the compound semiconductor constituting light absorption layer 40. The thickness of light absorption layer 40 can be, for example, about 3.0 μm. The thickness of light absorption layer 40 can be appropriately adjusted in accordance with the desired characteristics of the light-receiving device to be manufactured. Specifically, high sensitivity can be obtained by increasing the thickness of light absorption layer 40. The operation speed can be improved by reducing the thickness of light absorption layer 40.

Cap layer 51 is a semiconductor layer disposed on and in contact with second main surface 40B of light absorption layer 40. Cap layer 51 has a first main surface 51A and a second main surface 51B located on the opposite to first main surface 51A in the thickness direction. Cap layer 51 is in contact with second main surface 40B of light absorption layer 40 at first main surface 51A. Cap layer 51 is formed of a III-V compound semiconductor. As the III-V compound semiconductor constituting cap layer 51, for example, InP can be adopted. Specifically, for example, InP (n-InP) having an n-type conductivity is adopted as the compound semiconductor constituting cap layer 51. The concentration of n-type impurities (impurities that generate electrons as majority carriers) contained in the compound semiconductor constituting cap layer 51 can be set to, for example, about 1×10¹⁸ cm⁻³. In the present embodiment, the concentration of impurities that generate majority carriers is lower in first electric-field control layer 31 than in cap layer 51. The thickness of cap layer 51 can be, for example, about 500 nm.

Contact layer 52 is a semiconductor layer disposed on and in contact with second main surface 51B of cap layer 51. Contact layer 52 has a first main surface 52A and a second main surface 52B located on the opposite to first main surface 52A in the thickness direction. Contact layer 52 is in contact with second main surface 51B of cap layer 51 at first main surface 52A. Contact layer 52 is formed of a III-V compound semiconductor. As the III-V compound semiconductor constituting contact layer 52, for example, InGaAs can be adopted. Specifically, for example, InGaAs (n-InGaAs) having an n-type conductivity is adopted as the compound semiconductor constituting contact layer 52. The concentration of n-type impurities (impurities that generate electrons as majority carriers) contained in the compound semiconductor constituting contact layer 52 can be set to, for example, about 2× 10¹⁹ cm⁻³. The concentration of impurities that generate majority carriers is higher in contact layer 52 than in cap layer 51. The thickness of contact layer 52 may be, for example, about 200 nm. Cap layer 51 and contact layer 52 constitute a second-conductivity-type layer 50 having a second conductivity type.

In semiconductor stack 1 of the present embodiment, for example, Si (silicon) or the like can be adopted as the n-type impurity. As the p-type impurity, for example, Zn (zinc) or the like can be adopted.

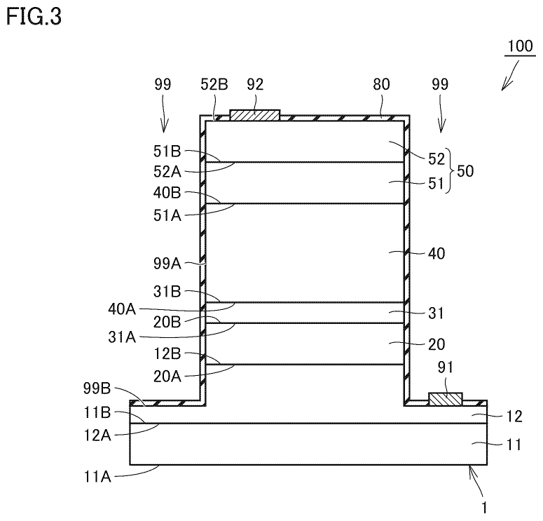

Next, an avalanche photodiode, which is an example of a light-receiving device fabricated using semiconductor stack 1, will be described. FIG. 3 is a schematic cross-sectional view showing the structure of an avalanche photodiode. Referring to FIG. 3, an avalanche photodiode 100 according to the present embodiment is fabricated using semiconductor stack 1 according to the present embodiment, and includes substrate 11, buffer layer 12, multiplication layer 20, first electric-field control layer 31, light absorption layer 40, cap layer 51, and contact layer 52, which are stacked in the same manner as semiconductor stack 1. In avalanche photodiode 100, a trench 99 is formed to penetrate contact layer 52, cap layer 51, light absorption layer 40, first electric-field control layer 31, and multiplication layer 20 and to reach buffer layer 12. That is, contact layer 52, cap layer 51, light absorption layer 40, first electric-field control layer 31, and multiplication layer 20 are exposed at a sidewall 99A of trench 99. A bottom wall 99B of trench 99 is located in buffer layer 12. That is, buffer layer 12 is exposed at bottom wall 99B of trench 99.

Avalanche photodiode 100 further includes a passivation film 80, a first electrode 91, and a second electrode 92. Passivation film 80 is disposed to cover bottom wall 99B of trench 99, sidewall 99A of trench 99, and second main surface 52B of contact layer 52. Passivation film 80 is formed of an insulator such as silicon nitride or silicon oxide.

An opening is formed in passivation film 80 covering bottom wall 99B of trench 99 so as to penetrate passivation film 80 in the thickness direction. First electrode 91 is disposed so as to fill the opening. First electrode 91 is disposed so as to be in contact with buffer layer 12 exposed from the opening. First electrode 91 is formed of a conductor such as metal. More specifically, first electrode 91 can be formed of, for example, Ti (titanium)/Pt (platinum)/Au (gold). First electrode 91 is in ohmic contact with buffer layer 12.

An opening is formed in passivation film 80 covering second main surface 52B of contact layer 52 so as to penetrate passivation film 80 in the thickness direction. Second electrode 92 is disposed so as to fill the opening. Second electrode 92 is disposed so as to be in contact with contact layer 52 exposed from the opening. Second electrode 92 is formed of a conductor such as metal. More specifically, second electrode 92 can be formed of, for example, Ti/Pt/Au. Second electrode 92 is in ohmic contact with contact layer 52.

Next, the operation of avalanche photodiode 100 of the present embodiment will be described. In operation, avalanche photodiode 100 is reverse biased. Specifically, in the present embodiment, a voltage is applied such that first electrode 91 is a negative electrode and second electrode 92 is a positive electrode. When light is incident on avalanche photodiode 100, the light is absorbed in light absorption layer 40, and pairs of electrons and holes are generated. The generated electrons and holes are extracted from avalanche photodiode 100 as a photocurrent signal, and thus light is detected.

The holes generated in light absorption layer 40 travel toward first electrode 91, which is a negative electrode, and reach multiplication layer 20 through first electric-field control layer 31. As described above, multiplication layer 20 of the present embodiment is a superlattice layer in which first element layer 21 formed of InP and second element layer 22 formed of GaAs₁₋ₓSbₓ (x is 0.3 to 1) are alternately stacked. In the superlattice layer, between InP constituting first element layer 21 and GaAs₁₋ₓSbₓ constituting second element layer 22, the difference ΔEv in energy level between valence bands is larger than the difference ΔEc in energy level between conduction bands. Therefore, the ionization rate ratio, which is the value of ΔEc/ΔEv, is small. In such a superlattice layer, when carriers drop from first element layer (barrier layer) 21 to second element layer (well layer) 22, the ionization coefficient of holes becomes larger than that of electrons, and thus the number of holes in multiplication layer 20 increases significantly as compared with the number of electrons. As a result, even when the number of pairs of electrons and holes generated in light absorption layer 40 is small, a photocurrent signal is easily detected. As described above, avalanche photodiode 100 of the present embodiment is a light-receiving device having high sensitivity. Semiconductor stack 1 of the present embodiment is a semiconductor stack suitable for manufacturing avalanche photodiode 100, and is a semiconductor stack capable of obtaining a light-receiving device having high sensitivity.

In the present embodiment, the ionization rate ratio in multiplication layer 20 can be set to less than 0.05. The ionization rate ratio in multiplication layer 20 can be calculated by fabricating an avalanche photodiode in which, in avalanche photodiode 100 of the present embodiment, the p-type semiconductor layer is an n-type semiconductor layer and the n-type semiconductor layer is a p-type semiconductor layer in addition to avalanche photodiode 100 of the present embodiment, and evaluating the electrical characteristics of both. In semiconductor stack 1 and avalanche photodiode 100 according to the present embodiment, first electric-field control layer 31 is not essential, but the use of first electric-field control layer 31 facilitates stable application of a strong electric field to the multiplication layer.

### Second Embodiment

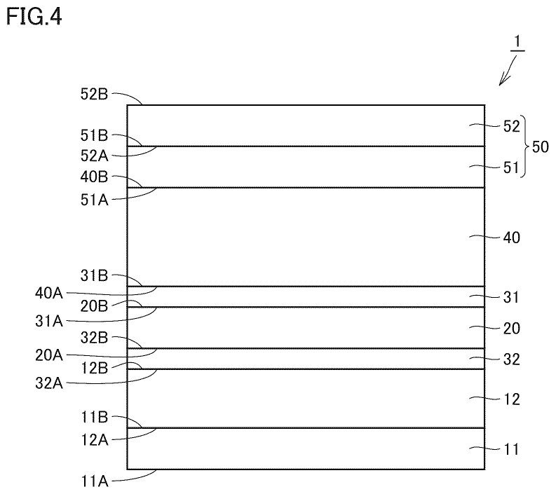

Next, a second embodiment which is another embodiment of the semiconductor stack and the avalanche photodiode of the present disclosure will be described. FIG. 4 is a schematic cross-sectional view showing the structure of a semiconductor stack. Referring to FIGS. 4 and 1, semiconductor stack 1 of the second embodiment further includes a second electric-field control layer 32 in addition to the structure of semiconductor stack 1 of the first embodiment. Avalanche photodiode 100 of the second embodiment further includes second electric-field control layer 32 in addition to the structure of avalanche photodiode 100 of the first embodiment.

Second electric-field control layer 32 is disposed between multiplication layer 20 and buffer layer 12. Second electric-field control layer 32 has a first main surface 32A and a second main surface 32B located on the opposite to first main surface 32A in the thickness direction. Second electric-field control layer 32 is in contact with second main surface 12B of buffer layer 12 at first main surface 32A and is in contact with first main surface 20A of multiplication layer 20 at second main surface 32B.

Second electric-field control layer 32 is formed of a III-V compound semiconductor. As the III-V compound semiconductor constituting second electric-field control layer 32, for example, InP can be adopted. Specifically, for example, InP (p-InP) having a p-type conductivity is adopted as the compound semiconductor constituting second electric-field control layer 32. Second electric-field control layer 32 is a semiconductor layer having the first conductivity type. The concentration of p-type impurities (impurities that generate holes as majority carriers) contained in the compound semiconductor constituting second electric-field control layer 32 can be set to, for example, about 5×10¹⁷ cm⁻³. The concentration of impurities that generate majority carriers is lower in second electric-field control layer 32 than in buffer layer 12. The thickness of second electric-field control layer 32 can be, for example, about 100 nm.

In the present embodiment, second electric-field control layer 32 is employed in addition to first electric-field control layer 31 described in the first embodiment. This makes it easier to stably apply a strong electric field to multiplication layer 20.

### Third Embodiment

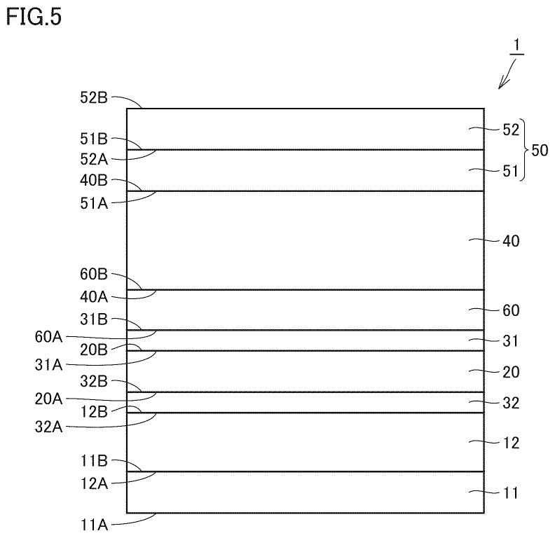

Next, a third embodiment which is still another embodiment of the semiconductor stack and the avalanche photodiode of the present disclosure will be described. FIG. 5 is a schematic cross-sectional view showing the structure of a semiconductor stack. Referring to FIGS. 5 and 4, semiconductor stack 1 of the third embodiment further includes a compositionally graded layer 60 in addition to the structure of semiconductor stack 1 of the second embodiment. Avalanche photodiode 100 of the third embodiment further includes compositionally graded layer 60 in addition to the structure of avalanche photodiode 100 of the second embodiment.

Compositionally graded layer 60 is disposed between first electric-field control layer 31 and light absorption layer 40. Compositionally graded layer 60 has a first main surface 60A and a second main surface 60B located on the opposite to first main surface 60A in the thickness direction. Compositionally graded layer 60 is in contact with second main surface 31B of first electric-field control layer 31 at first main surface 60A, and is in contact with first main surface 40A of light absorption layer 40 at second main surface 60B.

Compositionally graded layer 60 is formed of a III-V compound semiconductor. The energy level of the band edge of compositionally graded layer 60 has a value between the energy level of the band edge of first electric-field control layer 31 and the energy level of the band edge of light absorption layer 40. As the III-V compound semiconductor constituting compositionally graded layer 60, for example, InGaAsP can be adopted. The composition of InGaAsP constituting compositionally graded layer 60 may be constant in compositionally graded layer 60, but may be changed stepwise or continuously such that the energy level of the band edge of compositionally graded layer 60 approaches the energy level of the band edge of light absorption layer 40 from first main surface 60A toward second main surface 60B.

In the present embodiment, compositionally graded layer 60 is employed. This facilitates the movement of carriers between first electric-field control layer 31 and light absorption layer 40. As a result, semiconductor stack 1 and avalanche photodiode 100 of the present embodiment are a semiconductor stack and an avalanche photodiode capable of improving the operation speed of the avalanche photodiode.

### Fourth Embodiment

Next, a fourth embodiment which is still another embodiment of the semiconductor stack and the avalanche photodiode of the present disclosure will be described. Referring to FIGS. 1 to 3, semiconductor stack 1 and avalanche photodiode 100 according to the fourth embodiment have the same stacked structure as semiconductor stack 1 and avalanche photodiode 100 according to the first embodiment, but are different from the first embodiment in the materials of multiplication layer 20 and first electric-field control layer 31 and the conductivity types of the each layer.

In detail, referring to FIG. 2, first element layer 21 of the fourth embodiment is formed of AlᵤGa₁₋ᵤAs₁₋ₓSbₓ. Second element layer 22 is formed of In_{y}Ga_{1-y}As. Here, u is 0.2 to 1, x is 0.3 to 1, and y is 0.3 to 1. The lowermost layer and the uppermost layer of multiplication layer 20 are both formed of AlᵤGa₁₋ᵤAs₁₋ₓSbₓ. Referring to FIGS. 1 and 3, for example, AlGaAsSb can be adopted as the III-V compound semiconductor constituting first electric-field control layer 31 of the fourth embodiment. Further, unlike the case of the first embodiment, the conductivity type of buffer layer 12 is set to the n-type, while the conductivity type of first electric-field control layer 31, cap layer 51, and contact layer 52 is set to the p-type. The same values as in first embodiment can be adopted for the thickness of each layer and the concentration of impurities that generate majority carriers.

Next, the operation of avalanche photodiode 100 of the present embodiment will be described. In operation, avalanche photodiode 100 is reverse biased. Specifically, in the present embodiment, a voltage is applied such that first electrode 91 is a positive electrode and second electrode 92 is a negative electrode. That is, a voltage in the opposite direction to that in the first embodiment is applied to avalanche photodiode 100. When light is incident on avalanche photodiode 100, the light is absorbed in light absorption layer 40, and pairs of electrons and holes are generated. The generated electrons and holes are extracted from avalanche photodiode 100 as a photocurrent signal, and thus light is detected.

Here, the electrons generated in light absorption layer 40 travel toward first electrode 91, which is a positive electrode, and reach multiplication layer 20 through first electric-field control layer 31. As described above, multiplication layer 20 of the present embodiment is a superlattice layer in which first element layer 21 formed of AlᵤGa₁₋ᵤAs₁₋ₓSbₓ (u is 0.2 to 1, and x is 0.3 to 1) and second element layer 22 formed of In_{y}Ga_{1-y}As (y is 0.3 to 1) are alternately stacked. In this superlattice layer, between AlᵤGa₁₋ᵤAs₁₋ₓSbₓ constituting first element layer 21 and In_{y}Ga_{1-y}As constituting second element layer 22, the difference ΔEv in energy level between valence bands is smaller than the difference ΔEc in energy level between conduction bands. Therefore, the ionization rate ratio, which is the value of ΔEv/ΔEc, is small. In such a superlattice layer, when carriers drop from first element layer (barrier layer) 21 to second element layer (well layer) 22, the ionization coefficient of electrons becomes larger than that of holes, and thus the number of electrons in multiplication layer 20 increases significantly as compared to that of holes. As a result, even when the number of pairs of electrons and holes generated in light absorption layer 40 is small, a photocurrent signal is easily detected. As described above, avalanche photodiode 100 of the present embodiment is a light-receiving device having high sensitivity. Semiconductor stack 1 of the present embodiment is a semiconductor stack suitable for manufacturing avalanche photodiode 100, and is a semiconductor stack capable of obtaining a light-receiving device having high sensitivity.

In the present embodiment, the ionization rate ratio in multiplication layer 20 can be set to less than 0.05. In semiconductor stack 1 and avalanche photodiode 100 according to the present embodiment, first electric-field control layer 31 is not essential, but the use of first electric-field control layer 31 facilitates stable application of a strong electric field to the multiplication layer.

### <Modification 1>

Next, modification 1 of the fourth embodiment will be described. Referring to FIGS. 4 and 1, semiconductor stack 1 of modification 1 further includes second electric-field control layer 32 in addition to the structure of semiconductor stack 1 of the fourth embodiment, as in the case of the second embodiment. Avalanche photodiode 100 of modification 1 further includes second electric-field control layer 32 in addition to the structure of avalanche photodiode 100 of the fourth embodiment, as in the case of the second embodiment. Second electric-field control layer 32 is formed of a III-V compound

semiconductor. As the III-V compound semiconductor constituting second electric-field control layer 32, for example, AlGaAsSb can be adopted. Specifically, for example, AlGaAsSb (n-AlGaAsSb) having an n-type conductivity is adopted as the compound semiconductor constituting second electric-field control layer 32. The thickness of second electric-field control layer 32 and the concentration of impurities that generate majority carriers can be the same as those in the second embodiment.

In this modification, second electric-field control layer 32 is employed in addition to first electric-field control layer 31 described in the fourth embodiment. This makes it easier to stably apply a strong electric field to multiplication layer 20.

### <Modification 2>

Next, modification 2 of the fourth embodiment will be described. Referring to FIGS. 5 and 4, semiconductor stack 1 of modification 2 further includes compositionally graded layer 60 in addition to the structure of semiconductor stack 1 of modification 1, as in the case of the third embodiment. Avalanche photodiode 100 of modification 2 further includes compositionally graded layer 60 in addition to the structure of avalanche photodiode 100 of modification 1, as in the case of the third embodiment.

Compositionally graded layer 60 is formed of a III-V compound semiconductor. The energy level of the band edge of compositionally graded layer 60 has a value between the energy level of the band edge of first electric-field control layer 31 and the energy level of the band edge of light absorption layer 40. As the III-V compound semiconductor constituting compositionally graded layer 60, for example, AlGaAsSb can be adopted. The ratio of the contents of Al and Ga in AlGaAsSb constituting compositionally graded layer 60 is set so that the energy level of the band edge in compositionally graded layer 60 is a value between the energy level of the band edge of first electric-field control layer 31 and the energy level of the band edge of light absorption layer 40. The composition of AlGaAsSb constituting compositionally graded layer 60 may be constant in compositionally graded layer 60, but may be changed stepwise or continuously such that the energy level of the band edge of compositionally graded layer 60 approaches the energy level of the band edge of light absorption layer 40 from first main surface 60A toward second main surface 60B.

In this modification, compositionally graded layer 60 is employed. This facilitates the movement of carriers between first electric-field control layer 31 and light absorption layer 40. As a result, semiconductor stack 1 and avalanche photodiode 100 of the present modification are a semiconductor stack and an avalanche photodiode capable of improving the operation speed of the avalanche photodiode.

### Fifth Embodiment

Next, a fifth embodiment which is still another embodiment of the semiconductor stack and the avalanche photodiode of the present disclosure will be described. Referring to FIGS. 1 to 3, semiconductor stack 1 and avalanche photodiode 100 according to the fifth embodiment have the same stacked structure as semiconductor stack 1 and avalanche photodiode 100 according to the first embodiment, but are different from the first embodiment in the materials of multiplication layer 20 and first electric-field control layer 31 and the conductivity types of the each layer.

In detail, referring to FIG. 2, first element layer 21 of the fifth embodiment is formed of AlᵤGa₁₋ᵤAs₁₋ₓSbₓ. Second element layer 22 is formed of GaAs_{1-z}Sb_{z}. Here, u is 0.2 to 1, x is 0.3 to 1, and z is 0.3 to 1. The lowermost layer and the uppermost layer of multiplication layer 20 are both formed of AlᵤGa₁₋ᵤAs₁₋ₓSbₓ. Referring to FIGS. 1 and 3, for example, AlGaAsSb can be adopted as the III-V compound semiconductor constituting first electric-field control layer 31 of the fifth embodiment. Further, unlike the case of the first embodiment, the conductivity type of buffer layer 12 is set to the n-type, while the conductivity type of first electric-field control layer 31, cap layer 51, and contact layer 52 is set to the p-type. The same values as in first embodiment can be adopted for the thickness of each layer and the concentration of impurities that generate majority carriers.

Next, the operation of avalanche photodiode 100 of the present embodiment will be described. In operation, avalanche photodiode 100 is reverse biased. Specifically, in the present embodiment, a voltage is applied such that first electrode 91 is a positive electrode and second electrode 92 is a negative electrode. That is, a voltage in the opposite direction to that in the first embodiment is applied to avalanche photodiode 100. When light is incident on avalanche photodiode 100, the light is absorbed in light absorption layer 40, and pairs of electrons and holes are generated. The generated electrons and holes are extracted from avalanche photodiode 100 as a photocurrent signal, and thus light is detected.

Here, the electrons generated in light absorption layer 40 travel toward first electrode 91, which is a positive electrode, and reach multiplication layer 20 through first electric-field control layer 31. As described above, multiplication layer 20 of the present embodiment is a superlattice layer in which first element layer 21 formed of AlᵤGa₁₋ᵤAs₁₋ₓSbₓ (u is 0.2 to 1, and x is 0.3 to 1) and second element layer 22 formed of GaAs_{1-z}Sb_{z} (z is 0.3 to 1) are alternately stacked. In this superlattice layer, between Al Ga₁₋ᵤAs₁₋ₓSbₓ constituting first element layer 21 and GaAs_{1-z}Sb_{z} constituting second element layer 22, the difference ΔEv in energy level between valence bands is smaller than the difference ΔEc in energy level between conduction bands. Therefore, the ionization rate ratio, which is the value of ΔEv/ΔEc, is small. In such a superlattice layer, when carriers drop from first element layer (barrier layer) 21 to second element layer (well layer) 22, the ionization coefficient of electrons becomes larger than that of holes, and thus the number of electrons in multiplication layer 20 increases significantly as compared to that of holes. As a result, even when the number of pairs of electrons and holes generated in light absorption layer 40 is small, a photocurrent signal is easily detected. As described above, avalanche photodiode 100 of the present embodiment is a light-receiving device having high sensitivity. Semiconductor stack 1 of the present embodiment is a semiconductor stack suitable for manufacturing avalanche photodiode 100, and is a semiconductor stack capable of obtaining a light-receiving device having high sensitivity.

In the present embodiment, the ionization rate ratio in multiplication layer 20 can be set to less than 0.05. In semiconductor stack 1 and avalanche photodiode 100 according to the present embodiment, first electric-field control layer 31 is not essential, but the use of first electric-field control layer 31 facilitates stable application of a strong electric field to the multiplication layer.

### <Modification 1>

Next, modification 1 of the fifth embodiment will be described. Referring to FIGS. 4 and 1, semiconductor stack 1 of modification 1 further includes second electric-field control layer 32 in addition to the structure of semiconductor stack 1 of the fifth embodiment, as in the case of the second embodiment. Avalanche photodiode 100 of modification 1 further includes second electric-field control layer 32 in addition to the structure of avalanche photodiode 100 of the fifth embodiment, as in the case of the second embodiment.

Second electric-field control layer 32 is formed of a III-V compound semiconductor. As the III-V compound semiconductor constituting second electric-field control layer 32, for example, AlGaAsSb can be adopted. Specifically, for example, AlGaAsSb (n-AlGaAsSb) having an n-type conductivity is adopted as the compound semiconductor constituting second electric-field control layer 32. The thickness of second electric-field control layer 32 and the concentration of impurities that generate majority carriers can be the same as those in the second embodiment.

In this modification, second electric-field control layer 32 is employed in addition to first electric-field control layer 31 described in the fifth embodiment. This makes it easier to stably apply a strong electric field to multiplication layer 20.

### <Modification 2>

Next, modification 2 of the fifth embodiment will be described. Referring to FIGS. 5 and 4, semiconductor stack 1 of modification 2 further includes compositionally graded layer 60 in addition to the structure of semiconductor stack 1 of modification 1, as in the case of the third embodiment. Avalanche photodiode 100 of modification 2 further includes compositionally graded layer 60 in addition to the structure of avalanche photodiode 100 of modification 1, as in the case of the third embodiment.

Compositionally graded layer 60 is formed of a III-V compound semiconductor. The energy level of the band edge of compositionally graded layer 60 has a value between the energy level of the band edge of first electric-field control layer 31 and the energy level of the band edge of light absorption layer 40. As the III-V compound semiconductor constituting compositionally graded layer 60, for example, AlGaAsSb can be adopted. The ratio of the contents of Al and Ga in AlGaAsSb constituting compositionally graded layer 60 is set so that the energy level of the band edge in compositionally graded layer 60 is a value between the energy level of the band edge of first electric-field control layer 31 and the energy level of the band edge of light absorption layer 40. The composition of AlGaAsSb constituting compositionally graded layer 60 may be constant in compositionally graded layer 60, but may be changed stepwise or continuously such that the energy level of the band edge of compositionally graded layer 60 approaches the energy level of the band edge of light absorption layer 40 from first main surface 60A toward second main surface 60B.

In this modification, compositionally graded layer 60 is employed. This facilitates the movement of carriers between first electric-field control layer 31 and light absorption layer 40. As a result, semiconductor stack 1 and avalanche photodiode 100 of the present modification are a semiconductor stack and an avalanche photodiode capable of improving the operation speed of the avalanche photodiode.

It should be understood that the embodiments disclosed herein are illustrative in all respects and not restrictive in any respect. The scope of the present invention is defined by the appended claims rather than the foregoing description, and is intended to include all modifications within the scope and meaning equivalent to the appended claims.

What is claimed is:

1. A semiconductor stack comprising:
a first-conductivity-type layer of a first conductivity type, the first-conductivity-type layer being formed of a III-V compound semiconductor;
a multiplication layer formed of a III-V compound semiconductor;
a light absorption layer formed of a III-V compound semiconductor; and
a second-conductivity-type layer of a second conductivity type different from the first conductivity type, the second-conductivity-type layer being formed of a III-V compound semiconductor,
wherein the first-conductivity-type layer, the multiplication layer, the light absorption layer, and the second-conductivity-type layer are stacked in this order,
the multiplication layer is a superlattice layer including a first element layer and a second element layer disposed in contact with the first element layer, and
the first element layer is an InP layer and the second element layer is a GaAs₁₋ₓSbₓ layer where x is 0.3 to 1, or
the first element layer is an AlᵤGa₁₋ᵤAs₁₋ₓSbₓ layer and the second element layer is an In_{y}Ga_{1-y}As layer where u is 0.2 to 1, x is 0.3 to 1, and y is 0.3 to 1, or the first element layer is an AlᵤGa₁₋ᵤAs₁₋ₓSbₓ layer and the second element layer is a GaAs_{1-z}Sb_{z} layer where u is 0.2 to 1, x is 0.3 to 1, and z is 0.3 to 1.

2. The semiconductor stack according to claim 1, wherein a main surface of the multiplication layer on a side of the first-conductivity-type layer and a main surface of the multiplication layer on a side of the light absorption layer are each formed of the first element layer.

3. The semiconductor stack according to claim 2, wherein the first element layer is an InP layer and the second element layer is a GaAs₁₋ₓSbₓ layer where x is 0.3 to 1.

4. The semiconductor stack according to claim 1, further comprising a first electric-field control layer of the second conductivity type, the first electric-field control layer being formed of a III-V compound semiconductor and disposed between the multiplication layer and the light absorption layer.

5. The semiconductor stack according to claim 4, further comprising a second electric-field control layer of the first conductivity type, the second electric-field control layer being formed of a III-V compound semiconductor and disposed between the multiplication layer and the first-conductivity-type layer.

6. The semiconductor stack according to claim 4, further comprising a compositionally graded layer which is formed of a III-V compound semiconductor and disposed between the first electric-field control layer and the light absorption layer and whose energy level of a band edge has a value between an energy level of a band edge of the first electric-field control layer and an energy level of a band edge of the light absorption layer.

7. The semiconductor stack according to claim 6,
wherein the compositionally graded layer includes
a first main surface which is a main surface on a side of the first electric-field control layer, and
a second main surface which is a main surface on a side of the light absorption layer, and
a composition of the compositionally graded layer changes stepwise such that the energy level of the band edge of the compositionally graded layer approaches the energy level of the band edge of the light absorption layer from the first main surface toward the second main surface.

8. The semiconductor stack according to claim 6,
wherein the compositionally graded layer includes
a first main surface which is a main surface on a side of the first electric-field control layer, and
a second main surface which is a main surface on a side of the light absorption layer, and
a composition of the compositionally graded layer changes continuously such that the energy level of the band edge of the compositionally graded layer approaches the energy level of the band edge of the light absorption layer from the first main surface toward the second main surface.

9. A light-receiving device comprising:
the semiconductor stack according to claim 1; and
an electrode disposed on the semiconductor stack.
